(19) United States
(12) Patent Application Publication
(10) Pub. No.: US 2009/0120500 A1
(43) Pub. Date: May 14, 2009

(54) SOLAR CELL PACKAGE FOR SOLAR CONCENTRATOR

(76) Inventors: Eric Prather, Santa Clara, CA (US); Hing Wah Chan, San Jose, CA (US); Andrzej Kurek, Campbell, CA (US)

Correspondence Address: BUCKLEY, MASCHOFF & TALWALKAR LLC, 50 LOCUST AVENUE, NEW CANAAN, CT, 06840, US

(21) Appl. No.: 12/118,026

(22) Filed: May 9, 2008

Related U.S. Application Data
(60) Provisional application No. 61/031,946, filed on Feb. 27, 2008.
(60) Provisional application No. 60/987,882, filed on Nov. 14, 2007.

(51) Int. Cl. H01L 31/00; B05D 5/12; B32B 37/14

(52) U.S. Cl. 136/259; 427/74; 156/60

(57) ABSTRACT

A system may include a substrate, and a solar cell including a top side and a bottom side, the top side having an active area and the bottom side coupled to the substrate. A frame may be coupled to the substrate, the frame defining an upper opening above the active area and a lower opening above the active area and between the active area and the upper opening. The lower opening may be smaller than the upper opening in at least one dimension, and an optical element may be disposed within the upper opening.

In some aspects, the lower opening is defined by a portion of the frame extending substantially parallel to the top side of the solar cell. In some aspects, the frame includes a first wall and a second wall opposing the first wall, an upper portion of the first wall is substantially parallel to an upper portion of the second wall, a lower portion of the first wall forms a first obtuse angle with the upper portion of the first wall, and a portion of the lower portion of the first wall defines a first side of the lower opening.

### CROSS REFERENCE TO RELATED APPLICATIONS

This application claims priority to Provisional Application Ser. No. 60/987,882, filed Nov. 14, 2007 and entitled “Devices for Retaining an Optical Element on a Solar Cell”, and to Provisional Application Ser. No. 61/031,946, filed Feb. 27, 2008 and entitled “Solar Cell Package for Solar Concentrator”, the contents of which are incorporated by reference herein for all purposes.

### BACKGROUND

A concentrating solar power unit may operate to concentrate incoming light onto a solar cell. It may be desirable to couple an optical element to the solar cell in order to increase an acceptance angle of the concentrating solar power unit, to homogenize the light source over the surface of the cell, and/or to further focus the light. A top (i.e., incoming) surface of the optical element should be retained in a particular spatial position relative to other optical elements in the system, and a bottom (i.e., outgoing) surface of the optical element should be retained in a particular spatial position relative to an active area of the solar cell. A size and weight of the optical element typically prohibit bonding the optical element directly to the fragile surface of the active area as a means of achieving this positioning.

Some conventional concentrating solar power units use a three part mounting scheme to retain an optical element on a solar cell. The solar cell is mounted to a front side of a substrate, and the front side of the substrate is also mounted to a back side of a printed circuit board. A lower holder is mounted to a front side of the printed circuit board. Both the lower holder and the printed circuit board define openings to allow incoming light to pass to the solar cell. The openings are filled with a PDMS (silicone) gel and an optical element is placed in the openings such that the lower holder positions the bottom of the optical element over cell. The gel is cured between the bottom of the optical element and the solar cell to a thickness greater than the final operating thickness.

An upper holder is then placed to position the top of the optical element over the cell and to exert some compressive force against the cell. The gel is therefore compressed when the upper holder is placed. This compression may push out bubbles that may have formed during the cure and fixes a gap between the optical element and the cell.

The above-described compression may fail to eliminate all of the bubbles that exist after curing the gel. Also, overcompression may cause the optical element to damage the cell. The gel itself may flow out of the gap over time (e.g., due to thermal pumping, etc), thereby degrading the optical coupling. The lower holder may be subject to oxidation if it receives highly concentrated light during operation. Products of the oxidation may be absorbed into the optical coupling or may be deposited on the optical element, degrading the optical performance and possibly leading to failure of the power unit.

Improved systems to retain an optical element on a solar cell are desired. Such systems may improve manufacturability, the retention of the optical element, the maintenance of the optical coupling and/or the quality of an optical coupling.

### BRIEF DESCRIPTION OF THE DRAWINGS

The construction and usage of embodiments will become readily apparent from consideration of the following specification as illustrated in the accompanying drawings, in which like reference numerals designate like parts.

FIG. 1 is a perspective view of a substrate and a solar cell according to some embodiments.

FIG. 2A is a perspective view of a substrate, a solar cell and a frame according to some embodiments.

FIG. 2B is a cross-sectional side view of a substrate, a solar cell and a frame according to some embodiments.

FIGS. 3A through 3C comprise various views of a frame according to some embodiments.

FIG. 4A is a perspective view of a substrate, a solar cell, a frame, a cap and optical coupling material according to some embodiments.

FIG. 4B is a cross-sectional side view of a substrate, a solar cell, a frame, a cap and optical coupling material according to some embodiments.

FIG. 5A is a cross-sectional side view of a substrate, a solar cell, a frame, a cap, an optical element and optical coupling material according to some embodiments.

FIG. 5B is a perspective cutaway view of an apparatus according to some embodiments.

FIG. 6 is a perspective view of an apparatus according to some embodiments.

FIG. 7A is a perspective view of a substrate, a solar cell, a frame, a cap and optical coupling material according to some embodiments.

FIG. 7B is a cross-sectional side view of a substrate, a solar cell, a frame, a cap and optical coupling material according to some embodiments.

FIG. 8 is an exploded perspective view of an array of concentrating solar radiation collectors according to some embodiments.

FIG. 9 is a perspective view of an array of concentrating solar radiation collectors according to some embodiments.

FIGS. 10A through 10C comprise various views of a frame according to some embodiments.

FIG. 11A is a perspective view of a substrate, a solar cell and a frame according to some embodiments.

FIG. 11B is a cross-sectional side view of a substrate, a solar cell and a frame according to some embodiments.

FIG. 12A is a perspective view of a substrate, a solar cell, a frame, a cap and optical coupling material according to some embodiments.

FIG. 12B is a cross-sectional side view of a substrate, a solar cell, a frame, a cap and optical coupling material according to some embodiments.

FIG. 12C is a cross-sectional side view of a substrate, a solar cell, a frame, a cap, an optical element and optical coupling material during insertion of the optical element according to some embodiments.

FIG. 12D is a cross-sectional side view of a substrate, a solar cell, a frame, a cap, an optical element and optical coupling material after insertion of the optical element according to some embodiments.

### DETAILED DESCRIPTION

The following description is provided to enable any person in the art to make and use the described embodiments and sets forth the best mode contemplated by for carrying out some embodiments. Various modifications, however, will remain readily apparent to those in the art.

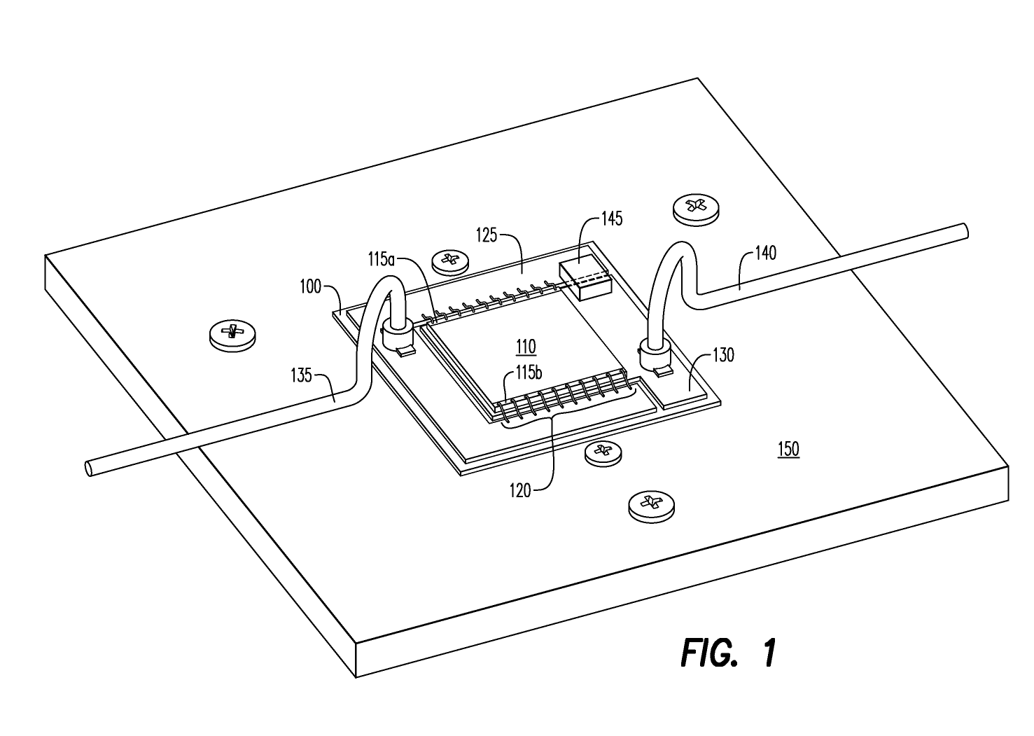

FIG. 1 is a perspective view of integrated circuit package substrate 100 and solar cell 110 according to some embodiments. Substrate 100 may comprise a single molded piece of material (e.g., a molded leadframe) or may comprise a suitable substrate with conductive elements deposited thereon using photolithography, lamination, or any other suitable technique.

Substrate 100 may comprise a metalized ceramic substrate according to some embodiments. A ceramic substrate may be less susceptible to deterioration due to stray concentrated light than conventional solar cell packaging materials. In some specific embodiments, substrate 100 comprises metalized alumina. Embodiments of substrate 100 may comprise any combination of one or more suitable materials, the selection of which may take into account heat dissipation, thermal expansion, strength and/or other qualities.

Solar cell 110 may comprise a III-V solar cell, a II-VI solar cell, a silicon solar cell, or any other type of solar cell that is or becomes known. Solar cell 110 may comprise any number of active, dielectric and metallization layers, and may be fabricated using any suitable methods that are or become known.

Solar cell 110 may receive photons at an active area located on the illustrated top side of solar cell 110, and may generate charge carriers (i.e., holes and electrons) in response to the photons. In this regard, solar cell 110 may comprise three distinct junctions deposited using any suitable method, including but not limited to molecular beam epitaxy and/or molecular organic chemical vapor deposition. The junctions may include a Ge junction, a GaAs junction, and a GaInP junction. Each junction exhibits a different band gap energy, which causes each junction to absorb photons of a particular range of energies.

According to the depicted embodiment, conductive contacts 115a and 115b are disposed on an upper side of solar cell 110. Each of conductive contacts 115a and 115b may comprise any suitable metal contact, and may include a thin adhesion layer (e.g., Ni or Cr), an ohmic metal (e.g., Ag), a diffusion barrier layer (e.g., TiW or TiW:N), a solderable metal (e.g., Ni), and a passivation metal (e.g., Au). Wirebonds 120a and 120b electrically couple conductive contacts 115a and 115b to conductive element 125. Conductive contacts 115a and 115b therefore exhibit a same polarity according to some embodiments.

A further conductive contact (not shown) may be disposed on a lower side of solar cell 110. This conductive contact may exhibit a polarity opposite from the polarity of conductive contacts 115a and 115b. This conductive contact is electrically coupled to conductive element 130 using silver die attach epoxy or solder according to some embodiments. Embodiments are not limited to the illustrated number, location and polarities of conductive contacts.

Conductive elements 125 and 130 may comprise any suitable conductive materials and may be formed using any suitable techniques. Embodiments are not limited to the illustrated shapes and relative sizes of conductive elements 125 and 130. Substrate 100 is considered herein to comprise conductive elements 125 and 130. Accordingly, FIG. 1 depicts the coupling of solar cell 110 to substrate 100.

By virtue of the foregoing arrangement, current may flow between wires 135 and 140 while solar cell 110 actively generates charge carriers. If solar cell 110 is faulty or otherwise fails to generate charge carriers, bypass diode 145 may electrically couple conductive element 125 to conductive element 130 in response to a received external signal. Bypass diode 145 therefore allows current to flow between wires 135 and 140 and through any external circuit to which wires 135 and 140 are connected.

Heatsink 150 may be coupled to a “back” side of substrate 100 using silver die attach epoxy, thermal grease, curable thermal grease, silicone adhesive, and/or any other suitable compound. Heatsink 150 may comprise aluminum or any other composition to facilitate dissipation of heat from substrate 100. Heatsink 150 may also include structures to facilitate mounting the illustrated apparatus to a support. According to some embodiments, substrate 100 itself comprises a heatsink, and heatsink 150 is not employed.

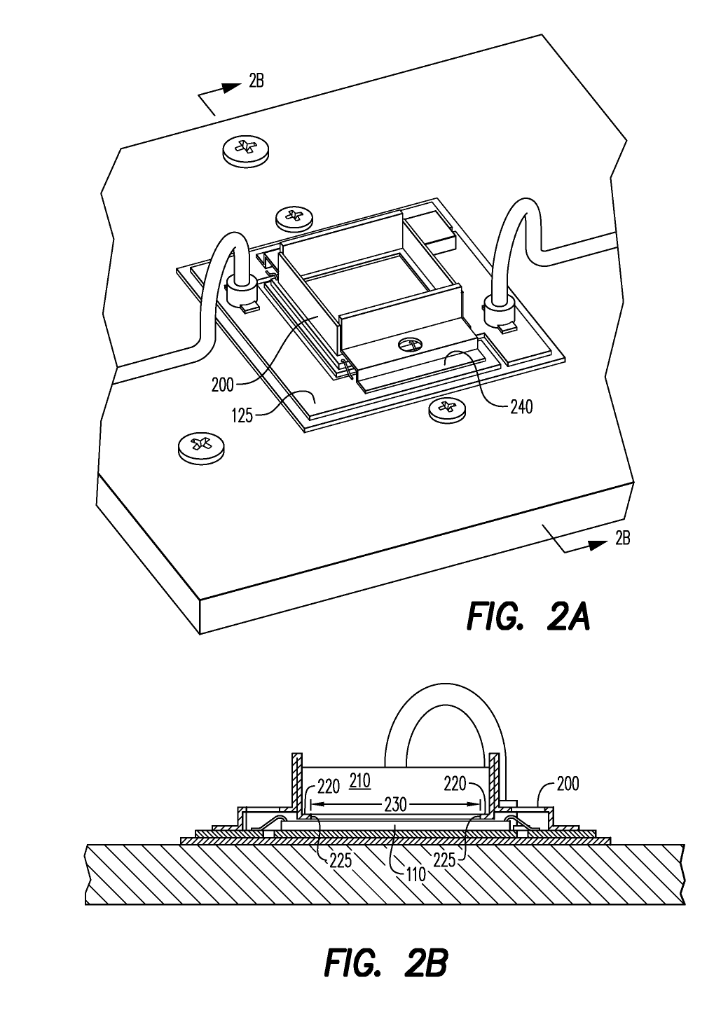

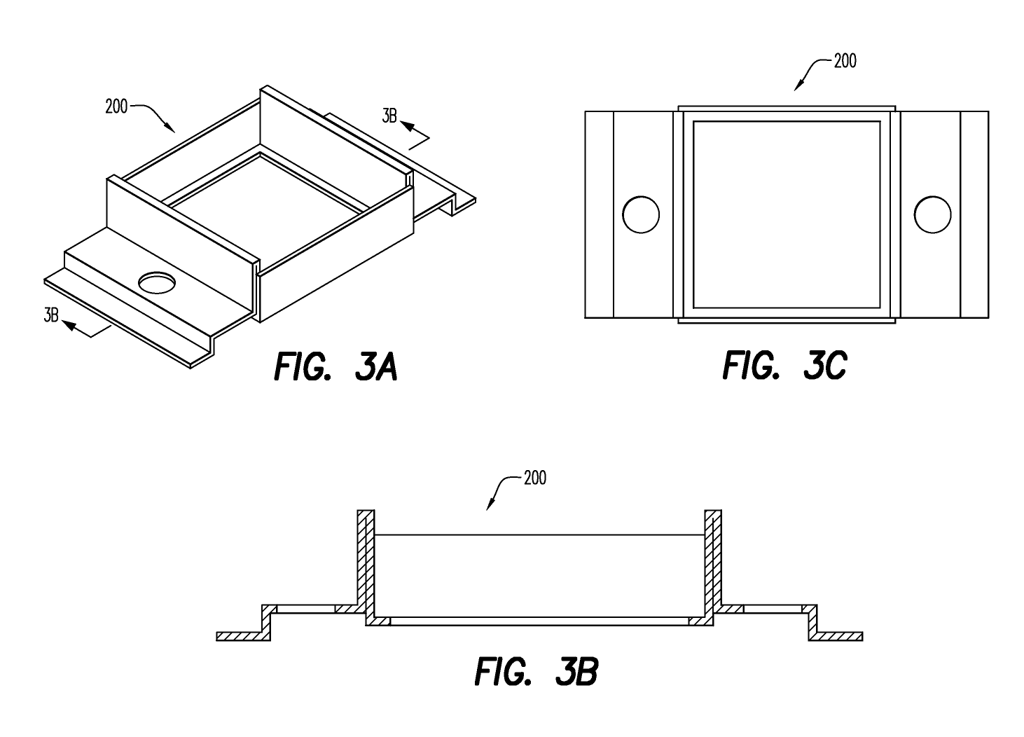

FIG. 2A is a perspective view and FIG. 2B is a cross-sectional side view of frame 200 coupled to the FIG. 1 apparatus according to some embodiments. FIGS. 3A through 3C comprise various views of frame 200 to further explain the illustrated relationships according to some embodiments. In some embodiments, frame 200 may be used to hold optical coupling material as well as to assist positioning an optical element (e.g., an optical rod, an optical prism). Frame 200 may comprise metal (e.g., Al, Cu), ceramic, and/or other materials that are not likely to oxidize or melt if attached directly to substrate 100 or to another heat sink.

Frame 200 defines upper opening 210 above an active area of solar cell 110 and lower opening 230 above the active area. Lower opening 230 is between the active area and upper opening 210. Lower opening 230 is smaller than upper opening 210 in at least one dimension. This size difference may facilitate placement of an optical element over the active area in some embodiments.

In the illustrated embodiment, portion 220 of frame 200 defines lower opening 230, and portion 220 extends substantially parallel to the top side of solar cell 110. Portion 220 includes distal end 225 which, as will be described below, may facilitate suitable deposition of an optical coupling material on the top side of solar cell 110. FIG. 2B shows a small gap between portion 220 and the top side of solar cell 110. In some embodiments, portion 220 may contact the top side of solar cell 110.

Frame 200 includes legs 240. Each of legs 240 is coupled to conductive element 125 and extends over one or more wirebonds 120. Each of legs 240 may, as shown, define a hole through which an encapsulant may be deposited onto wirebonds 120. Legs 240 may be epoxied to conductive element 125 in some embodiments. Frame 200 may be comolded into a lid (or overmold) of solar cell 110 in some embodiments, which may reduce a need for legs 240.

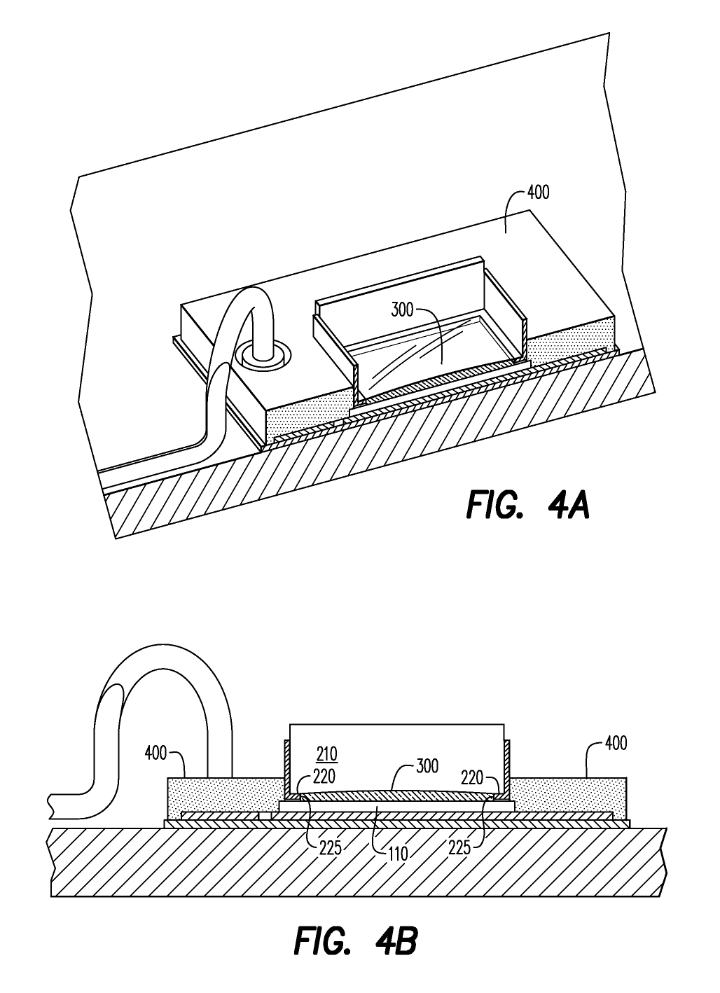

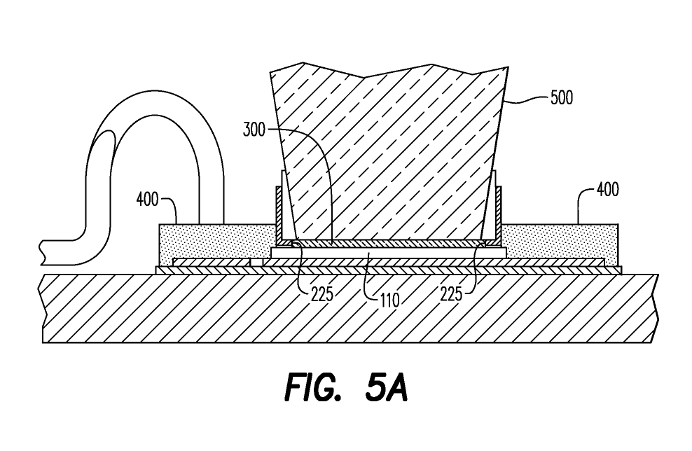

FIG. 4A is a perspective view and FIG. 4B is a cross-sectional side view of optical coupling material 300 and cap 400 coupled to the FIG. 2A and FIG. 2B apparatus according to some embodiments. As shown, a height of frame 200 with respect to solar cell 110 is greater than a height of cap 400 with respect to solar cell 110, but embodiments are not limited thereto.

Optical coupling material 300 is disposed on solar cell 110. Optical coupling material 300 may cover an active area of solar cell 110 and thereby provide protection thereof during handling/shipping. Optical coupling material 300 may comprise silicone gel or any other material(s) having suitable optical, thermal and physical properties. Optical coupling material 300 may be deposited on solar cell 110 using any techniques that are or become known.

Again, frame portion 220 is shown separated from a top side of cell 110. Optical coupling material 300 may be deposited such that its sides are in contact with distal end 225 of frame portion 220. Such an arrangement may facilitate curing material 300 to a convex meniscus as shown in FIGS. 4A and 4B.

If cured material 300 is soft, material 300 may be cured to any desired degree prior to compression by an optical element as will be described below. Curing material 300 prior to placing the optical element may allow bubbles to escape during cure. Full or partial curing may allow a cured assembly to be shipped without an optical element in place, reducing shipping volume and reducing the likelihood of damage to the optical coupling due to shock during shipping.

Cap 400 may comprise a dielectric material covering at least portions of the conductive elements 125 and 130, diode 145, and legs 240. In some embodiments, cap 400 may prevent arcing between heat sink 150 and the conductive elements above substrate 100. An outer edge of cap 400 may be coupled to substrate 100 using high viscosity silicone prior to deposition of optical coupling material 300 to enhance the dielectric seal. Cap 400 may comprise a polymer and may protect the components which it covers against oxidation, burning, melting and/or other degradation.

In some embodiments such as that illustrated in FIGS. 4A and 4B, a height of frame 200 with respect to solar cell 110 is greater than a height of cap 400 with respect to solar cell 110. This latter feature may allow frame 200 to protect cap 400 (and the components underneath cap 400) from stray concentrated light exiting an optical element disposed in volume 210.

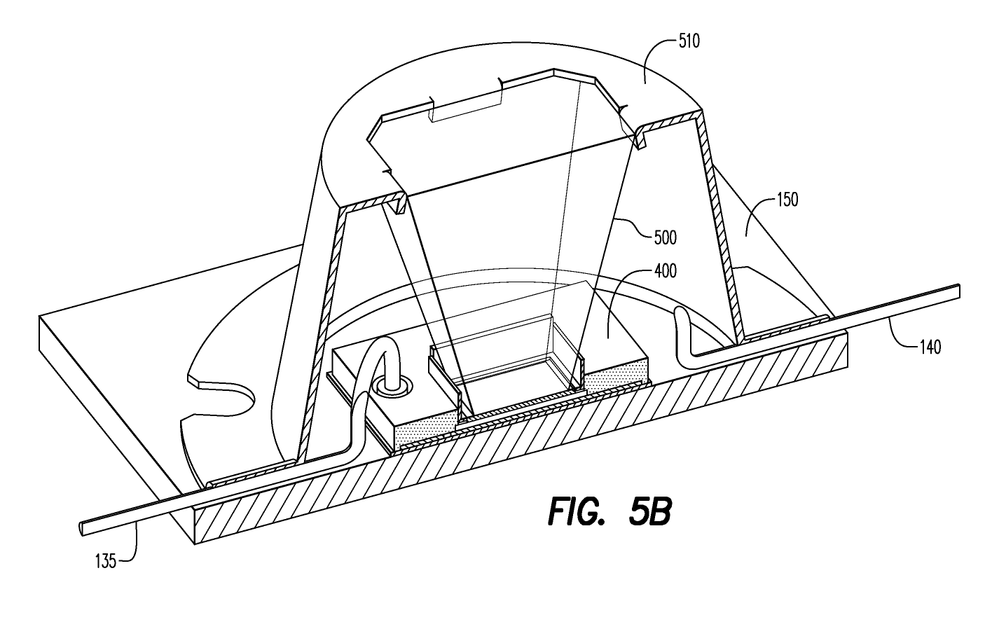

Such an optical element is illustrated in FIGS. 5A and 5B. Optical element 500 is shown disposed within upper opening 210 and in contact with optical coupling material 300. Optical element 500 may be configured to receive and manipulate desired wavelengths of light and/or pass the light to solar cell 110. For example, solar cell 110 may receive photons from optical element 500 and generate electrical charge carriers in response thereto. Optical element 500 may be deliberately designed to eliminate photons which would not result in electrical charge carriers, thereby reducing an operational temperature and improving the performance of solar cell 110.

The illustrated height of frame 200 may also assist in maintaining a horizontal position of a lower part of optical element 500 by strictly limiting a range of horizontal movement of element 500. The height of frame 200 may be equal to or less than the height of cap 400 in some embodiments and/or may not assist in used to maintaining the above-described horizontal position. For example, one or more sides of frame 200 above solar cell 110 may simply include portion 220, with no portion of frame 200 extending above portion 220.

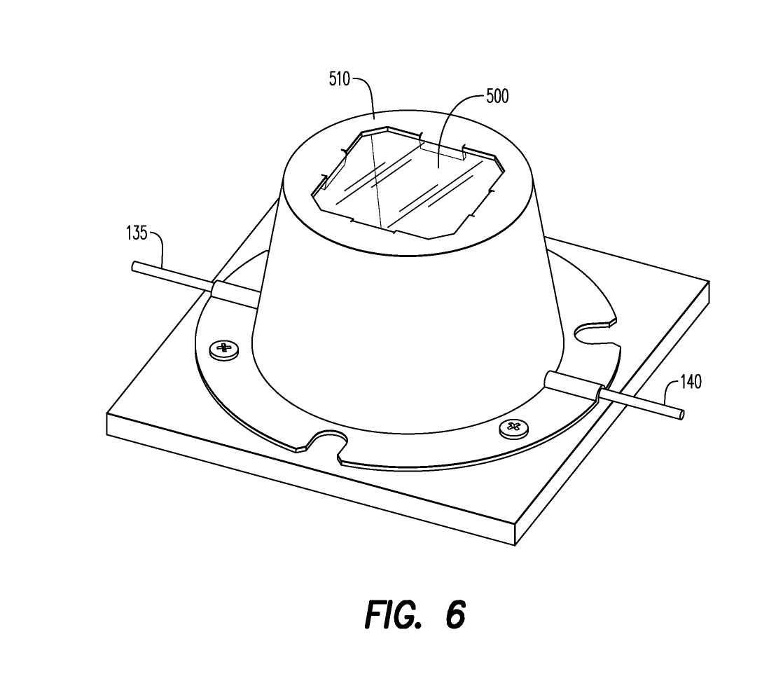

Optical element 500 may comprise any suitable composition and shape. Housing 510 assists retention of optical element 500 within volume 210 and may bias optical element 500 toward solar cell 210 so as to compress material 300 as shown. An upper surface of optical element 500 remains visible through an opening in housing 510 in order to receive concentrated light. Housing 510 is mechanically mounted to heatsink 150. FIG. 6 is a full perspective view of housing 510, the upper surface of optical element 500, and heatsink 150.

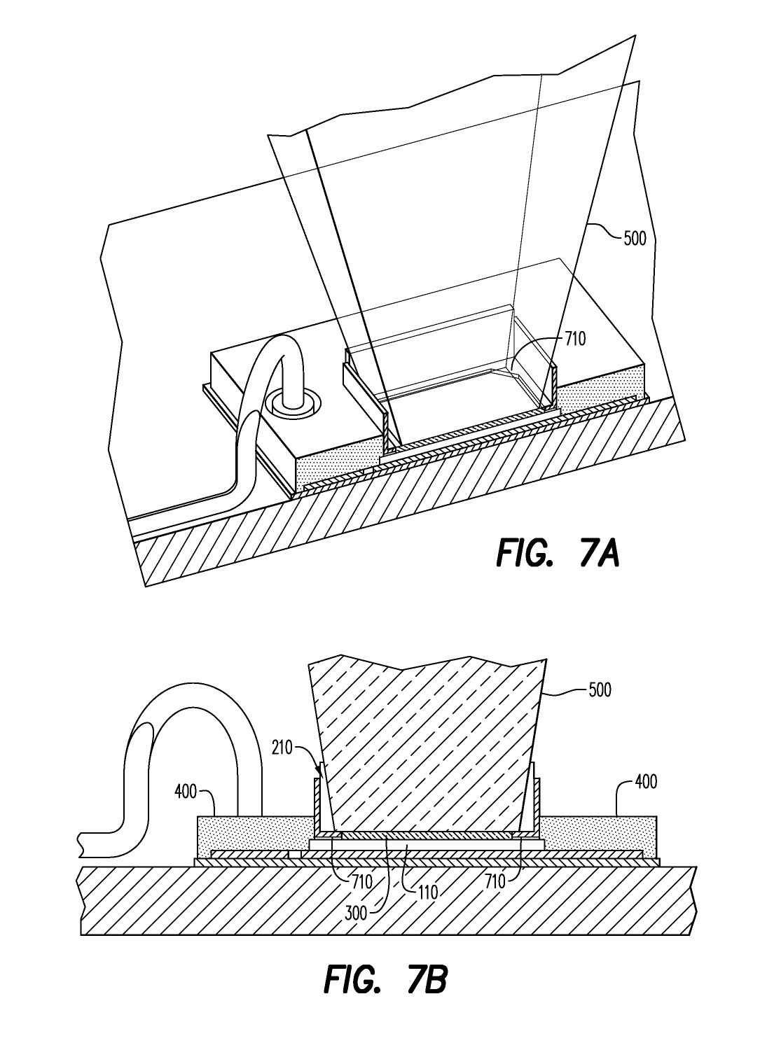

FIGS. 7A and 7B illustrate an embodiment similar to the embodiment of FIGS. 3A and 3B. However, frame 700 includes features 710 which contact a lower surface of optical element 500 when optical element 500 is placed in upper opening 210. Features 710 are located above and substantially parallel to the top side of solar cell 110. Features 710 may comprise any suitable location feature (e.g., small tabs that slip under the corners of the bottom surface of the optical element) and may provide a positive stop to preventing optical element 500 from contacting cell 110. Features 710 may further define lower opening 230, which remains smaller than upper opening 210 in at least one dimension. As mentioned above, frame 700 may or may not touch a top side of solar cell 110.

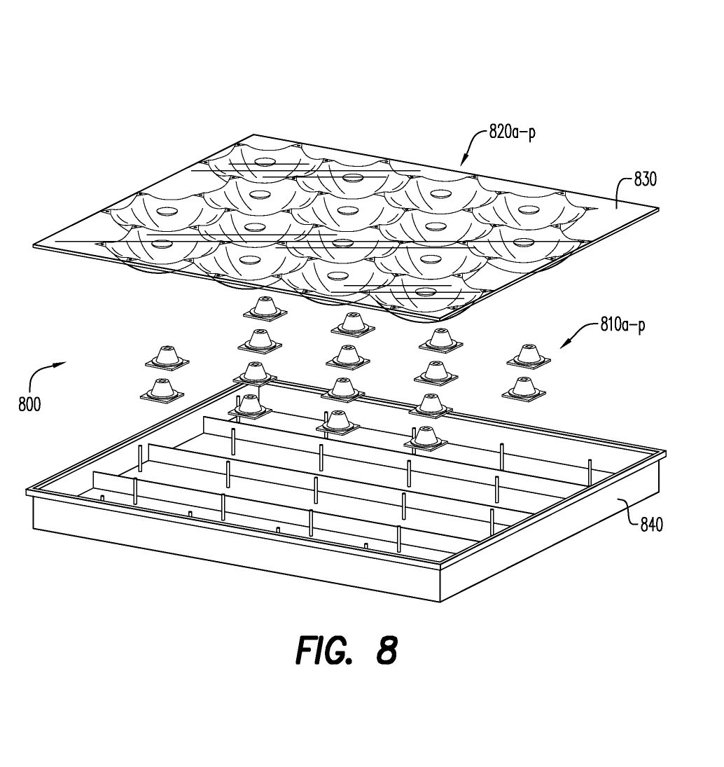

FIG. 8 is an exploded perspective view of apparatus 800 according to some embodiments. Apparatus 800 may generate electrical power from incoming solar radiation. Apparatus 800 comprises sixteen instantiations 810a-p of the FIG. 6 apparatus. Wires 135 and 140 of each of apparatuses 810a-p may be connected in series to create an electrical circuit during reception of light by apparatus 800. For clarity, wires 135 and 140 are not illustrated. Embodiments are not limited to the arrangement shown in FIG. 8.

Each of apparatuses 810a-p is associated with one of concentrating optics 820a-p. As described in U.S. Patent Application Publication No. 2006/0266408, each of concentrating optics 820a-p includes a primary mirror to receive incoming solar radiation and a secondary mirror to receive radiation reflected by the primary mirror. Each secondary mirror then reflects the received radiation toward an exposed surface of optical rod 500 within a corresponding one of apparatuses 810a-p.

A perimeter of each primary mirror may be substantially hexagonal to allow adjacent sides to closely abut one another as shown. In some embodiments, a perimeter of each primary mirror is square-shaped. Each primary mirror may comprise low iron soda-lime or borosilicate glass with silver deposited thereon, and each secondary mirror may comprise silver and a passivation layer formed on a substrate of soda-lime glass. The reflective coatings of the primary and secondary mirrors may be selected to provide a desired spectral response to the wavelengths of solar radiation to be collected, concentrated and converted to electricity by apparatus 800.

Each primary mirror and secondary mirror of concentrating optics 820a-p is physically coupled to substantially planar window or cover glazing 830. Each of apparatuses 800a-p is to be coupled to backpan 840. Backpan 840 may comprise any suitable shape and/or materials and may provide strength, electrical routing, and heat dissipation to apparatus 800.

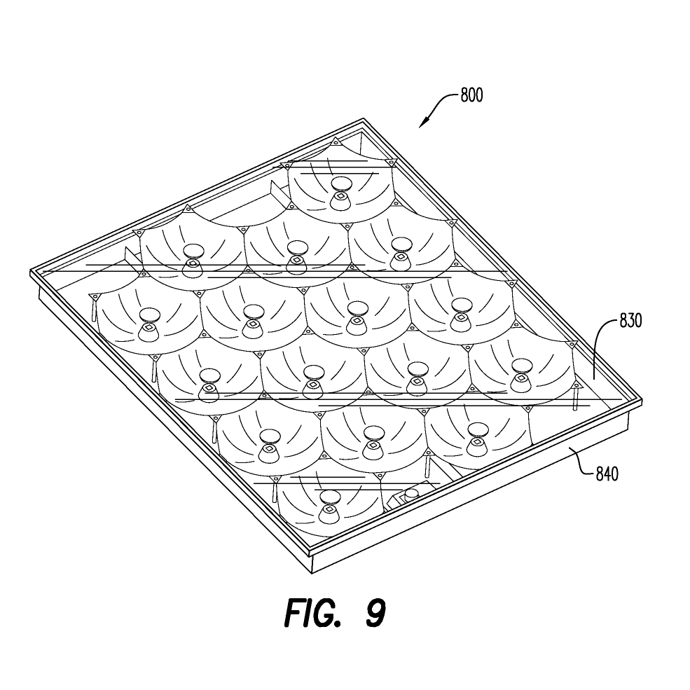

FIG. 9 is a perspective view of assembled apparatus 800 according to some embodiments. As shown, window or cover glazing 830 is secured to backpan 840. Each of apparatuses 810a-p passes through an opening in its corresponding primary mirror and is positioned beneath its corresponding secondary mirror.

The illustrated arrangement allows an exposed surface of each optical element of apparatuses 810a-p to receive concentrated light. As described above, the received light is passed to a corresponding solar cell which generates electrical current in response. The electrical current generated by each of apparatuses 810a-p may be received by external circuitry coupled to backpan 840 in any suitable manner. Assembled apparatus 800 may be mounted on a sun-tracking device to maintain a desired position relative to the sun during daylight hours.

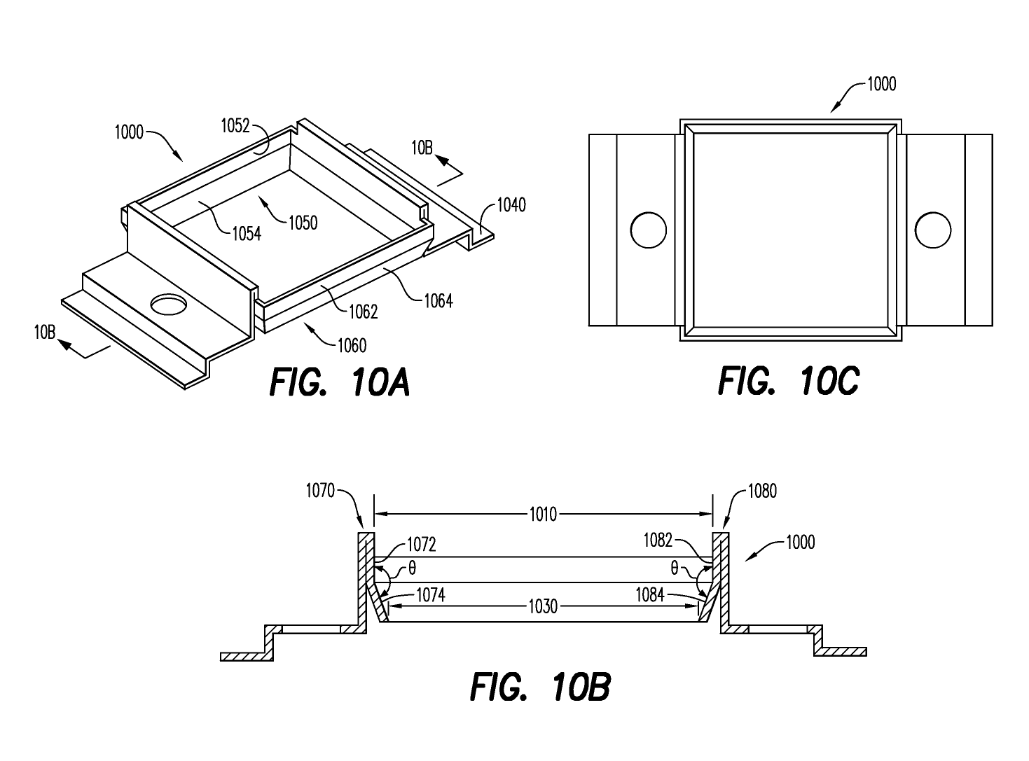

FIGS. 10A through 10C comprise various views of frame 1000 according to some embodiments. Frame 1000 may be used in place of frames 200 and 700 in the embodiments shown in FIGS. 6, 8 and 9. Frame 1000 may comprise any suitable composition, and defines upper opening 1010 and lower opening 1030. Lower opening 1030 is smaller than upper opening 1010 in at least one dimension. Frame 1000 also includes legs 1040, each of which may define a hole through which an encapsulant may be deposited during assembly.

Frame 1000 includes opposing walls 1050 and 1060 as well as opposing walls 1070 and 1080. Upper portion 1052 of wall 1050 is substantially parallel to upper portion 1062 of wall 1060. Moreover, lower portion 1054 of wall 1050 forms an obtuse angle θ with upper portion 1052, and a portion of lower portion 1054 defines a first side of lower opening 1030. The foregoing features may facilitate proper placement of an optical element as will be described below.

According to the illustrated embodiment, lower portion 1064 of wall 1060 forms an obtuse angle θ with upper portion 1062, and a portion of lower portion 1064 defines a second side of lower opening 1030. Furthermore, upper portion 1072 of wall 1070 is substantially parallel to upper portion 1082 of wall 1080, lower portion 1074 of wall 1070 forms an obtuse angle θ with upper portion 1072, and a portion of lower portion 1074 defines a first side of lower opening 1030. Lower portion 1084 of wall 1080 forms an obtuse angle θ with upper portion 1082, and a portion of lower portion 1084 defines a first side of lower opening 1030.

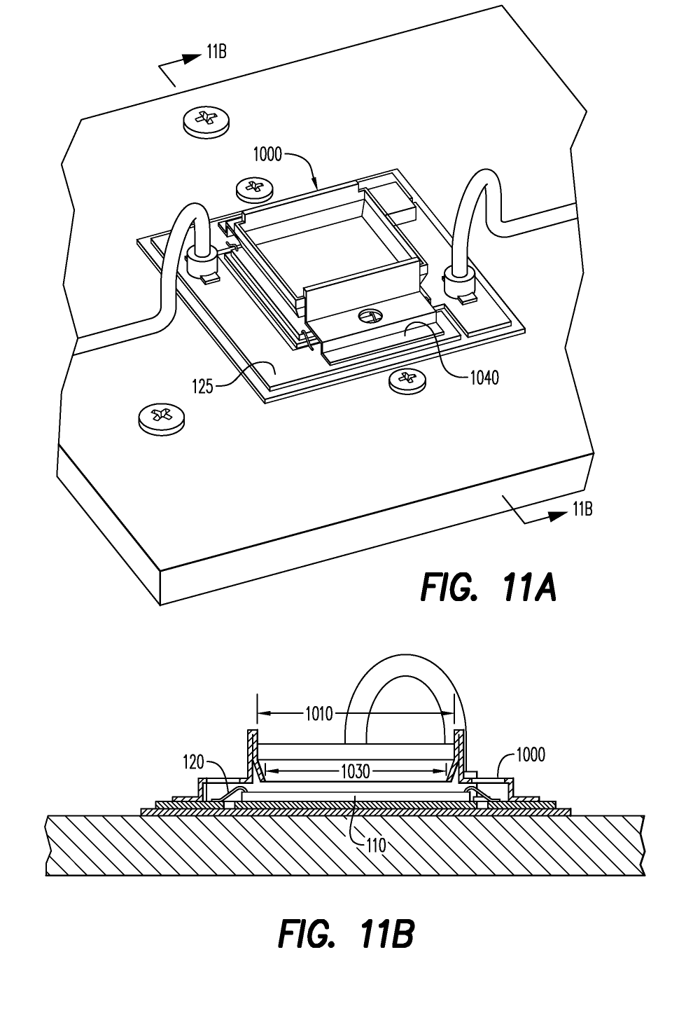

FIG. 11A is a perspective view and FIG. 11B is a cross-sectional side view of frame 1000 coupled to the FIG. 1 apparatus according to some embodiments. As shown, frame 1000 defines upper opening 1010 above an active area of solar cell 110 and lower opening 1030 above the active area. Lower opening 1030 is between the active area and upper opening 1010 and is smaller than upper opening 1010 in at least one dimension. This size difference may facilitate placement of an optical element over the active area in some embodiments. Although FIG. 11B shows a small gap between frame 1000 and the top side of solar cell 110, frame 1000 may contact the top side of solar cell 110 in some embodiments.

Each of legs 1040 is coupled (e.g., epoxied) to conductive element 125 and extends over one or more wirebonds 120. Each of legs 1040 also defines a hole through which an encapsulant may be deposited onto wirebonds 120. As an alternative to legs 1040, frame 1000 may be comolded into a lid (or overmold) of solar cell 110 in some embodiments.

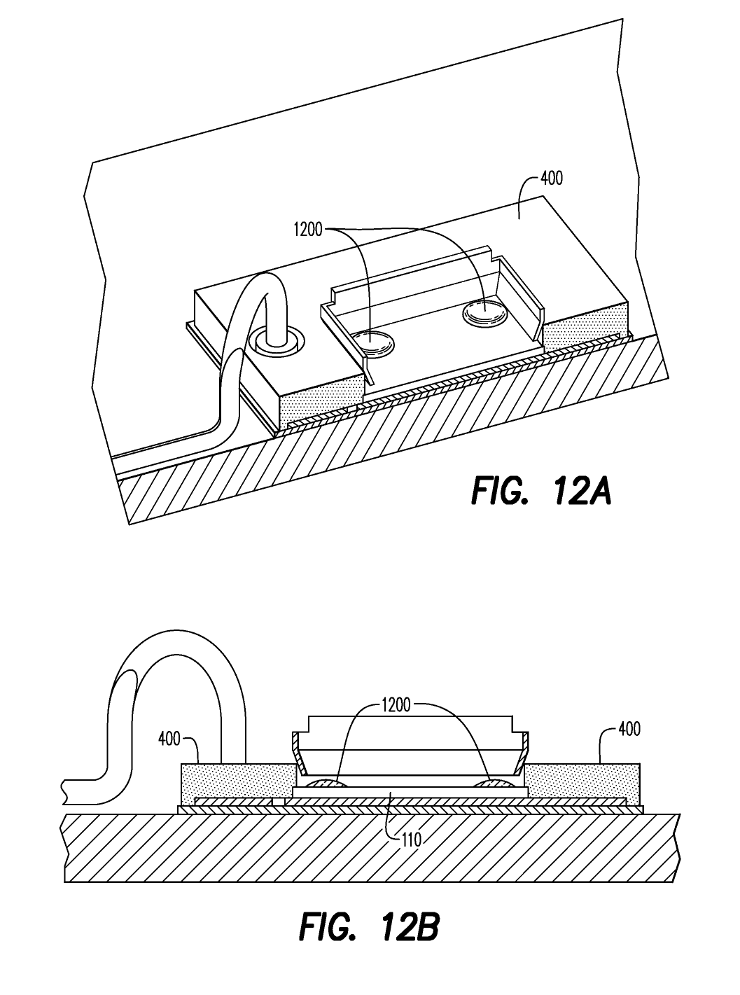

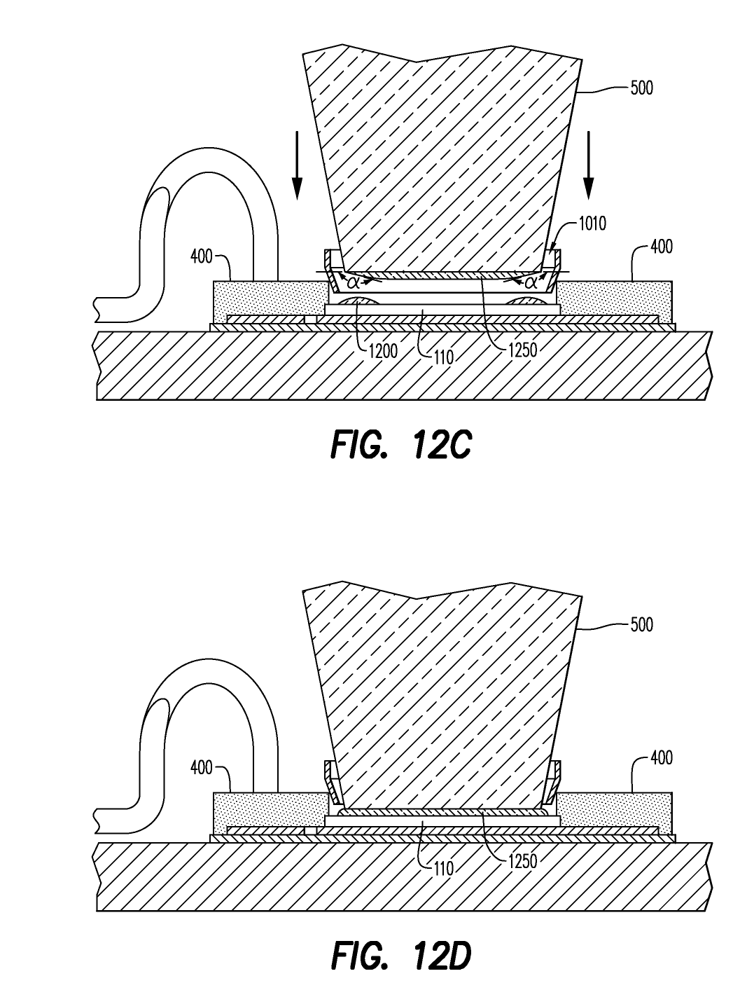

FIG. 12A is a perspective view and FIG. 12B is a cross-sectional side view of optical coupling material 1200 and cap 400 coupled to the FIG. 11A and FIG. 11B apparatus according to some embodiments. Optical coupling material 1200 is disposed near each corner of solar cell 110 (i.e., four separate portions), but embodiments are not limited thereto. For example, the number of portions of optical coupling material 1200 and/or their geometric arrangement may differ. In some embodiments, optical coupling material 1200 is dispensed so as to define the perimeter of a square on solar cell 110. Optical coupling material 300 may be deposited on solar cell 110 using a syringe or any other technique that is or becomes known.

Material 1200 may be cured to any desired degree prior to placement of an optical element as illustrated in FIGS. 12C and 12D. In this regard, FIG. 12C illustrates optical element 500 being placed within upper opening 1010 of frame 100. Optical coupling material 1250 has been deposited on an end of element 500 prior to the illustrated event. Optical coupling material 1250 may be partially or fully cured.

Optical coupling material 1250 and the end of optical element 500 are moved between the lower wall portions of frame 1000. Optical element 1250 may contact one or more lower wall portions of frame 1000 during this movement. Accordingly, frame 1000 may server to guide optical element 500 to a proper position above cell 110. At the conclusion of this movement, material 1250 may contact solar cell 110 as shown in FIG. 12D. As also shown, material 1250 may join with previously-deposited material 1200 to form an optical interface between optical element 500 and the active area of cell 110. Some embodiments do not include previously-deposited material such as material 1200.

In some embodiments, portions of material 1200 and/or material 1250 may flow over and at least partially cover one or more edges of solar cell 110 at the conclusion of movement represented in FIG. 12D. These portions may assist in passivating exposed p-n junctions on the edge of solar cell 110 which are thusly covered.

According to some embodiments, the obtuse angle θ mentioned above may be based on a wetting angle a of optical coupling material 1250 as deposited on the end of optical element 500. Such an arrangement facilitates unmolested passage of optical coupling material 1250 through frame 1000 while allowing the lower wall portions to guide optical element 500. The wetting angle α according to some embodiments ranges from 166 to 168 degrees and may range, in some embodiments, from 157 to 171 degrees. In either of these cases, θ may equal 115 degrees, but embodiments are not limited thereto.

The several embodiments described herein are solely for the purpose of illustration. Embodiments may include any currently or hereafter-known versions of the elements described herein. Therefore, persons in the art will recognize from this description that other embodiments may be practiced with various modifications and alterations.

What is claimed is:

1. An apparatus comprising:
a substrate;
a solar cell comprising a top side and a bottom side, the top side comprising an active area and the bottom side coupled to the substrate;
a frame coupled to the substrate, the frame defining an upper opening above the active area and a lower opening above the active area and between the active area and the upper opening, the lower opening being smaller than the upper opening in at least one dimension; and
an optical element disposed within the upper opening.

2. An apparatus according to claim 1,
wherein the lower opening is defined by a portion of the frame extending substantially parallel to the top side of the solar cell.

3. An apparatus according to claim 2, further comprising:
optical coupling material disposed on the solar cell and in the volume,
wherein a side of the disposed optical coupling material is in contact with a distal end of the portion of the frame.

4. An apparatus according to claim 1,
wherein the frame comprises a first wall and a second wall opposing the first wall,
wherein an upper portion of the first wall is substantially parallel to an upper portion of the second wall,
wherein a lower portion of the first wall forms a first obtuse angle with the upper portion of the first wall, and
wherein a portion of the lower portion of the first wall defines a first side of the lower opening.

5. An apparatus according to claim 4,
wherein a lower portion of the second wall forms a second obtuse angle with the upper portion of the second wall, and
wherein a portion of the lower portion of the second wall defines a second side of the lower opening.

6. An apparatus according to claim 5, wherein the obtuse angle is greater than 115 degrees.

7. An apparatus according to claim 1,
wherein the optical element is in contact with a portion of the frame above and substantially parallel to the top side of the solar cell.

8. An apparatus according to claim 1,
wherein the substrate comprises:
a first conductive element; and
one or more wirebonds electrically coupling the first conductive element to a conductive contact of the solar cell, and
wherein the frame comprises a leg coupled to the first conductive element and extending over the one or more wirebonds.

9. An apparatus according to claim 7, further comprising:
a cap covering at least a portion of the first conductive element and at least a portion of the leg,
wherein a height of the frame with respect to the solar cell is greater than a height of the cap with respect to the solar cell.

10. A method comprising:
coupling a bottom side of a solar cell to a substrate, the solar cell comprising a top side comprising an active area;
coupling a frame to the substrate, the frame defining an upper opening above the active area and a lower opening above the active area and between the active area and the upper opening, the lower opening being smaller than the upper opening in at least one dimension; and
placing an optical element within the upper opening.

11. A method according to claim 10,
depositing optical coupling material on the solar cell,
wherein a side of the deposited optical coupling material is in contact with a distal end of a portion of the frame defining the lower opening and extending substantially parallel to the top side of the solar cell.

12. A method according to claim 10, further comprising:
depositing optical coupling material on an end of the optical element prior to placing an optical element within the upper opening.

13. A method according to claim 12, further comprising:
at least partially curing the deposited optical coupling material prior to placing an optical element within the upper opening.

14. A method according to claim 13, further comprising:
depositing second optical coupling material on the top side of the solar cell prior to placing the optical element within the upper opening.

15. A method according to claim 13,
wherein the frame comprises a first wall and a second wall opposing the first wall,
wherein an upper portion of the first wall is substantially parallel to an upper portion of the second wall,
wherein a lower portion of the first wall forms a first obtuse angle with the upper portion of the first wall,
wherein the obtuse angle is greater than 115 degrees,
wherein a portion of the lower portion of the first wall defines a first side of the lower opening,
wherein a portion of the lower portion of the second wall defines a second side of the lower opening, and
wherein placing the optical element within the upper opening comprises moving the end of the optical element and the optical coupling material between the lower portion of the first wall and the lower portion of the second wall.

16. A method according to claim 10, wherein coupling the frame to the substrate comprises:
coupling a leg of the frame to a conductive element of the substrate,
the method further comprising:
attaching one or more wirebonds between a conductive contact of the solar cell and the conductive element,
wherein the leg extends over the one or more wirebonds.

17. A method according to claim 16, further comprising:
coupling a cap to the substrate to cover at least a portion of the first conductive element and at least a portion of the leg,
wherein a height of the frame with respect to the solar cell is greater than a height of the cap with respect to the solar cell.
